(19) United States
(12) Patent Application Publication
(10) Pub. No.: US 2008/0203526 A1
(43) Pub. Date: Aug. 28, 2008

(54) Semiconductor device equipped with thin-film circuit elements

(75) Inventor: Ichiro Mihara, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/072,210

(22) Filed: Feb. 25, 2008

(30) Foreign Application Priority Data
Feb. 26, 2007 (JP) 2007-045167

(51) Int. Cl. H01L 27/06

(52) U.S. Cl. 257/531; 257/E27.027

(57) ABSTRACT

A plurality of wirings, column-shaped electrodes, sealing films, and soldering balls, are provided on a third upper-layer insulating film formed on a silicon substrate. A spirally configured thin-film inductive element is disposed beneath the bottom surface of a ground insulating film formed beneath the silicon substrate. The inner and outer end portions of the thin-film inductive element are respectively connected to the wirings via a vertical conductor disposed in the silicon substrate. In this case, it is not required to secure a certain area otherwise needed for the formation of the thin-film inductive element over the surface of the third upper-layer insulating film that accommodates the wirings. Hence, even when the thin-film inductive element has been provided, it is possible to evade a feasibility to incur restraint on the distribution of the wirings formed over the surface of the third upper-layer insulating film.

### BACKGROUND OF THE INVENTION

1. Field of the Invention

The present invention relates to a semiconductor device.

2. Description of the Related Art

Japanese Patent No. 3540729 discloses a semiconductor device, which is referred to as the “Chip Size Package” and equipped with a plurality of spirally configured thin-film inductive elements that are respectively disposed on a semiconductor substrate in the form connected to a plurality of wirings disposed thereon. Further, this semiconductor device is fitted with column-shaped electrodes on the connecting pads connected to the wiring units, where a sealing film is formed in the periphery of the column-shaped electrodes, where the above device is further fitted with a plurality of soldering balls above the column-shaped electrodes.

Nevertheless, as disclosed in the Japanese Patent No. 3540729, since a plurality of wirings and spirally configured thin-film inductive elements connected to the wirings are respectively disposed on the semiconductor substrate and further fitted with column-shaped electrodes above the pad connected to the wirings, it is required to secure a certain area enough to form the spirally configured thin-film inductive elements in addition to the wiring formation area including the column-shaped electrodes on an identical layer on the semiconductor substrate, and thus, this in turn raises a problem in that distribution of the wirings is inevitably affected by restraint.

### SUMMARY OF THE INVENTION

Hence, the present invention aims at providing a semiconductor device, which evades restraint otherwise incurring to the distribution of wirings, and incorporates properly distributed wirings even when the device has been equipped with a spirally configured thin-film inductive element.

A plurality of wirings, column-shaped electrodes, sealing films, and soldering balls, are respectively disposed on the third upper-layer insulating film formed on a silicon substrate. A spirally configured thin-film inductive element is disposed beneath the ground insulating film formed beneath the silicon substrate. The inner and outer edge portions of the thin-film inductive film are respectively connected to the wirings via the vertical conductor formed through the silicon substrate. In this case, it is not necessary to secure a certain area otherwise needed for the formation of the thin film inductive element on the upper surface of the upper-layer insulating film, and thus, even when the thin-film inductive element has been provided, it is still possible to evade restraint otherwise affecting distribution of the wirings formed on the upper surface of the third upper-layer insulating film.

A semiconductor device provided in accordance with a first aspect of the present invention comprises a semiconductor substrate having a plurality of connecting pads formed on one-surface thereof; a plurality of wiring units disposed on the one-surface thereof in such a way as to be connected to the connecting pads; a thin-film circuit element formed on the other surface of the above semiconductor substrate; and a vertical conductor formed in the semiconductor substrate so as to enable the thin-film circuit element to be connected to the wiring units.

A semiconductor device provided in accordance with the second aspect of the present invention comprises a semiconductor substrate having a plurality of connecting pads formed on one-surface thereof; a plurality of wiring units disposed on the one-side surface of the semiconductor substrate in such a way as to be connected to the above connecting pads; a thin-film circuit element that is essentially a spirally configured thin-film inductive element disposed on the other side surface of the semiconductor substrate; and a vertical conductor formed in the above semiconductor substrate so as to enable the above thin-film circuit element to be connected to the wiring units.

A semiconductor device according to the third aspect of the present invention comprises a semiconductor device comprising: a semiconductor substrate having a plurality of connecting pads formed on the one-surface thereof; a plurality of first wiring units disposed on the one-surface of the semiconductor substrate in such a way as to be individually connected to the connecting pads; a thin-film circuit element formed on the one-surface of the above semiconductor substrate in such a way as to be connected to the above first wiring units; a plurality of second wiring units formed on the other surface of the above semiconductor substrate; and a vertical conductor formed in the above semiconductor substrate so as to enable the above first wiring unit to be connected to the above second wiring unit.

A semiconductor device provided in accordance with the fourth aspect of the present invention comprises: a semiconductor substrate having a plurality of connecting pads formed on the one-surface thereof; a plurality of first wiring units disposed on the one-surface of the above semiconductor substrate in such a way as to be connected to the above connecting pads; a thin-film circuit element, which is essentially a spirally configured thin-film inductive element provided on the one-surface of the semiconductor substrate in such a way as to be connected to the first wiring units; a plurality of second wiring units disposed on the other surface of the semiconductor substrate; and a vertical conductor formed in the above semiconductor substrate so as to enable the above first wiring units to be connected to the above second wiring units.

### BRIEF DESCRIPTION OF THE DRAWINGS

These objects and other objects and advantages of the present invention will become more apparent upon reading the following detailed description and the accompanying drawings in which:

FIG. 1 is a cross-sectional view of the essential components of the semiconductor device according to the first embodiment of the present invention;

FIG. 2 is a bottom view of the semiconductor device shown in FIG. 1;

FIG. 3 is a cross-sectional view of an initially prepared model according to an instance of a method for manufacturing the semiconductor device shown in FIG. 1;

FIG. 4 is a cross-sectional view of the model treated with a further process from the original model shown in FIG. 3;

FIG. 5 is a cross-sectional view of the serially prepared model treated with a further process from the configuration shown in FIG. 4;

FIG. 6 is a cross-sectional view of the serially prepared model treated with a further process from the configuration shown in FIG. 5;

FIG. 7 is a cross-sectional view of the serially prepared model treated with a further process from the configuration shown in FIG. 6;

FIG. 8 is a cross-sectional view of the serially prepared model treated with a further process from the configuration shown in FIG. 7;

FIG. 9 is a cross-sectional view of the serially prepared model treated with a further process from the configuration shown in FIG. 8;

FIG. 10 is a cross-sectional view of the serially prepared model treated with a further process from the configuration shown in FIG. 9;

FIG. 11 is a cross-sectional view of the serially prepared model treated with a further process from the configuration shown in FIG. 10;

FIG. 12 is a cross-sectional view of the serially prepared model treated with a further process from the configuration shown in FIG. 11;

FIG. 13 is a cross-sectional view of the serially prepared model treated with a further process from the configuration shown in FIG. 12;

FIG. 14 is a cross-sectional view of the serially prepared model treated with a further process from the configuration shown in FIG. 13;

FIG. 15 is a cross-sectional view of the serially prepared model treated with a further process from the configuration shown in FIG. 14;

FIG. 16 is a cross-sectional view of the serially prepared model treated with a further process from the configuration shown in FIG. 15;

FIG. 17 is a cross-sectional view of the serially prepared model treated with a further process from the configuration shown in FIG. 16;

FIG. 18 is a cross-sectional view of the serially prepared model treated with a further process from the configuration shown in FIG. 17;

FIG. 19 is a cross-sectional view of the essential components of the semiconductor device according to the second embodiment of the present invention;

FIG. 20 is a bottom view of the semiconductor device shown in FIG. 19;

FIG. 21 is a cross-sectional view of the essential components of the semiconductor device according to the third embodiment of the present invention;

FIG. 22 is a cross-sectional view of the essential components of the semiconductor device according to the fourth embodiment of the present invention; and

FIG. 23 is a cross-sectional view of the essential components of the semiconductor device according to the fifth embodiment of the present invention.

### DETAILED DESCRIPTION OF THE PREFERRED EMBODIMENTS

### The First Embodiment

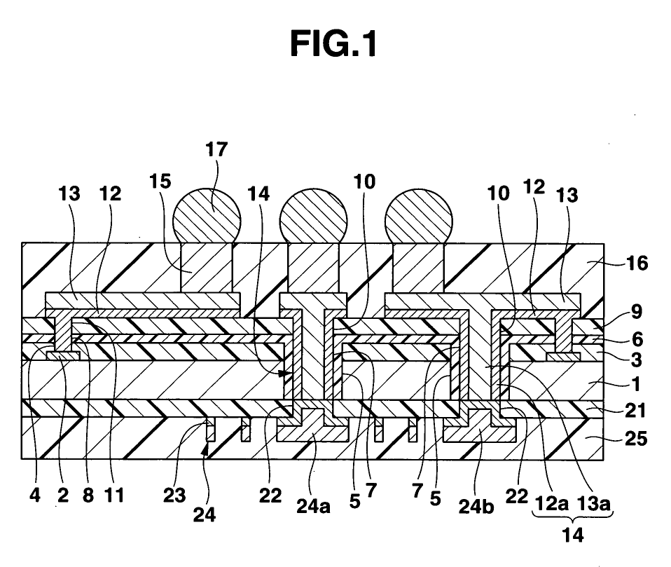

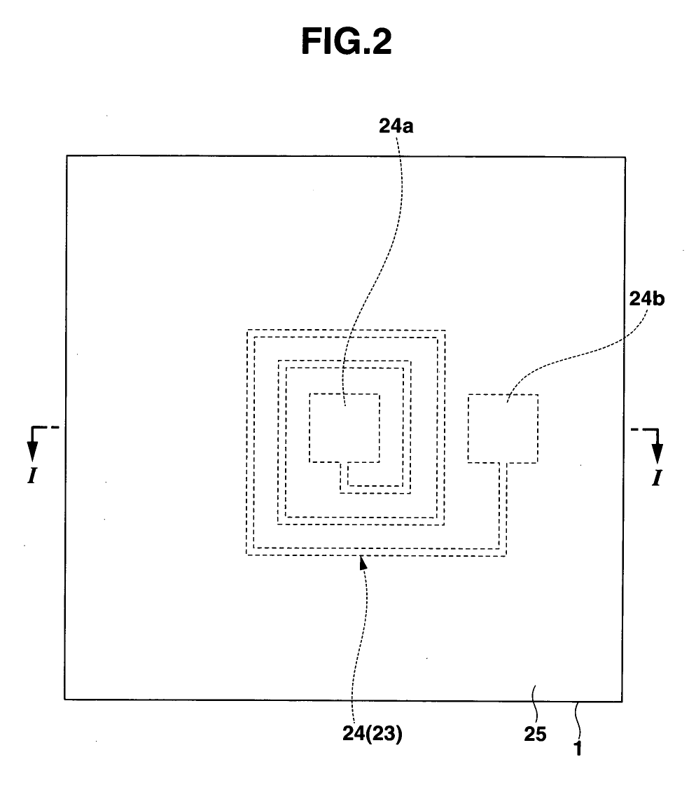

FIG. 1 designates the essential components of the semiconductor device according to the first embodiment of the present invention. FIG. 2 designates the bottom view thereof. In this case, FIG. 1 designates a cross-sectional view along the line I-I. This semiconductor device is generally referred to as the “Chip Size Package (CSP)”, which is provided with a silicon substrate as a semiconductor substrate 1 having a square plane configuration. A plurality of integrated circuits (not shown) each capable of exerting predetermined functions are disposed on the upper surface of the silicon substrate 1. A plurality of connecting pads 2 comprising metallic substance (Al) are disposed in linkage with the integrated circuits in the periphery of the upper surface of the silicon substrate 1.

The first upper-layer insulating film 3 made from silicon oxide is formed over the surface of the silicon substrate 1 except the center portions of the connecting pads 2. The center portion of each connecting pad 2 is exposed via the opening 4 formed through the first upper-layer insulating film 3. A plurality of through-holes 5 are formed through the center portions of the silicon substrate 1 and the first upper-layer insulating film 3 as well as the other predetermined portion (through a total of 2 locations).

The second upper-layer insulating film 6 made from silicon nitride is formed on the surface of the first upper-layer insulating film 3 including the inner wall surface of the through-holes 5. In this case, the second upper-layer insulating film 6 formed on the inner wall surface of the through-holes 5 is formed into a cylindrical configuration having another through-hole 7. Another opening 8 is formed through the second upper-layer insulating film 6 formed at an area corresponding to the other opening 4 that is formed through the first upper-layer insulating film 3.

The third upper-layer insulating film (protection film) 9 made from polyimide resin is formed on the surface of the second upper-layer insulating film 6. In this case, another opening 10 is formed through the third upper-layer insulating film 9 at a portion corresponding to the through-hole 7 formed through the second upper-layer insulating film 6. Further, another opening 11 is formed through the third upper-layer insulating film 9 at a portion corresponding to the opening 8 formed through the second upper-layer insulating film 6.

A ground metallic layer 12 made from copper is formed on the surface of the third upper-layer insulating film 9. A plurarity of wirings 13 made of copper are distributed on the surface of the ground metallic layer 12. An end portion of the each wirings 13 including the ground metallic layer 12 is connected to the connecting pads 2 via the openings 4, 8, and 11 formed through the first, second, and the third upper-layer insulating films 3, 6, and 9.

Predetermined portions of the wirings 13 including a couple of predetermined ground metallic layers 12 are jointly connected to the upper portion of the vertical conductor 14 comprising the through-hole 7 of the second upper-layer insulating film 6, the ground metallic layer 12a which is cylindrically formed over the inner wall surface of the opening 10 of the third upper-layer insulating film 9, and the copper portion 13a disposed inside the opening 10. In this case, the bottom surface of the vertical conductor 14 comprising the cylindrical ground metallic layer 12a and the copper portion 13a formed inside the opening 10 is flush with the bottom surface of the silicon substrate 1.

A plurality of column-shaped electrodes 15 made of copper are disposed on the surface of the connecting pads provided for the wirings 13. A sealing film 16 made from epoxy resin is formed over the surface of the third upper-layer insulating film 9 including the wirings 13 in the state in which the upper surface of the sealing film 16 is flush with the upper surface of the column-shaped electrodes 15. A number of soldering balls 17 are formed over the surfaces of the column-shaped electrodes 15. A ground insulating film 21 made from polyimide resin is formed beneath the silicon substrate 1. An opening 22 is formed through the ground insulating film 21 formed at an area corresponding to the bottom surface of the vertical conductor 14. As shown in FIG. 2, a ground metallic layer 23 which is made of copper as available for the thin-film inductive element is spirally formed. Further, a thin-film inductive element (a. thin-film circuit element) 24 made from copper is formed by covering the whole bottom surface of the ground metallic layer 23 for the thin-film inductive element 24. As shown in FIG. 2, the plan-view shape of the thin-film inductive element 24 is formed so as to be a spiral configuration.

The inner end portion 24a of the thin-film inductive element 24 including the ground metallic layer 23 for the thin-film inductive element 24 is connected to the bottom surface of the vertical conductor 14 via the opening 22 formed through the ground insulating film 21 at the center portion of the silicon substrate 1. The outer end portion 24b of the thin-film inductive film 24 including the ground metallic layer 23 for the thin-film inductive element 24 is connected to the bottom surface of the vertical conductor 14 via the opening 22 formed through the ground insulating film 21 at the other predetermined portion of the silicon substrate 1. A bottom layer over-coating film 25 formed of solder resist, etc. is formed beneath the ground insulating film 21 including the thin-film inductive element 24.

As described above, since the inventive semiconductor device is fitted with a plurality of wirings 13 connected to the column-shaped electrodes 15 on the upper-surface side of the silicon substrate 1 and also fitted with the thin-film inductive element 24 beneath the silicon substrate 1, it is not necessary to secure a certain area otherwise needed for the formation of the thin-film inductive element on the upper surface of the silicon substrate 1, in other words, on the upper surface of the third upper-layer insulating film 9 that accommodates formation of the wirings 13. Hence, even when the thin-film inductive film 24 has been formed, it is possible to evade the restraint affecting distribution of the wirings 13 formed on the upper surface of the third upper-layer insulating film 9. Accordingly, it is possible to provide a useful semiconductor device fitted with adequately distributed wirings 13.

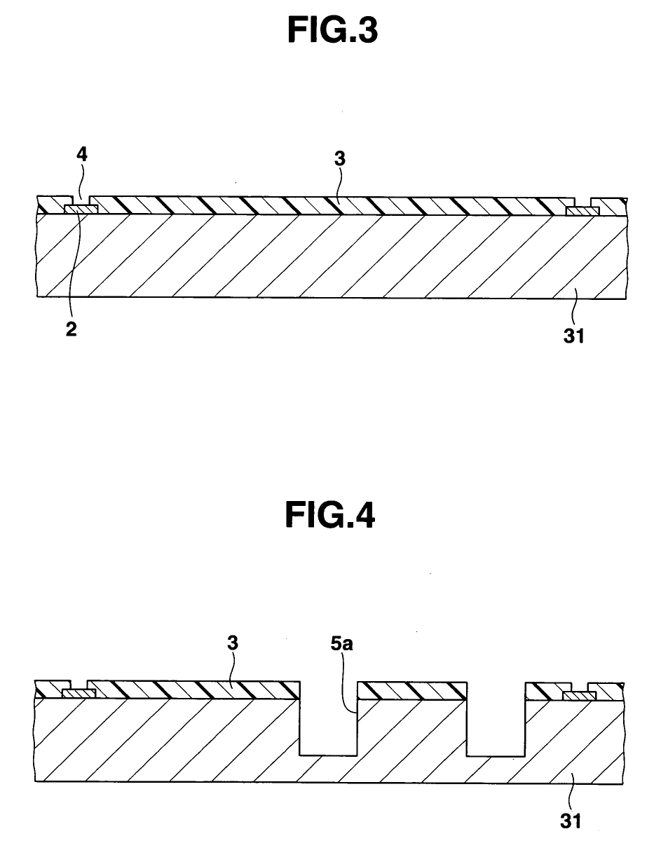

Next, a practical method for manufacturing the semiconductor device according to the present invention is described below. Initially, as shown in FIG. 3, a plurality of connecting pads 2 made of a metal such as aluminum and the first upper-layer insulating film 3 made from silicon oxide are respectively formed on the upper surface of the wafer-state silicon substrate (this will be referred to as the semiconductor wafer 31 hereinafter). Next, the semiconductor wafer 31 having the center portion of the connecting pads 2 being exposed via the opening 4 formed through the first upper-layer insulating film 3 is prepared.

In this case, a plurality of integrated circuits (not shown) capable of exerting the predetermined functions are formed in the area for accommodating formation of respective semiconductor devices on the upper surface of the above-cited semiconductor wafer 31. The connecting pads 2 are electrically connected to the integrated circuits formed in the individually corresponding areas. Thickness of the semiconductor wafers 31 is arranged to be thicker than the thickness of the silicon substrate shown in FIG. 1 to some extent.

Next, as shown in FIG. 4, by applying a laser beam irradiation process or a photo-lithographic process, a plurality of recessed portions 5b are formed through the first upper-layer insulating film 3 area and also through the area containing the through-holes 5 through the upper surface of the semiconductor wafer 31. For example, depth of each of the recessed portions 5a is arranged to be deeper by approximately 20 μm than the total thickness of the first upper-layer insulating film 3 and the silicon substrate 1 shown in FIG. 1.

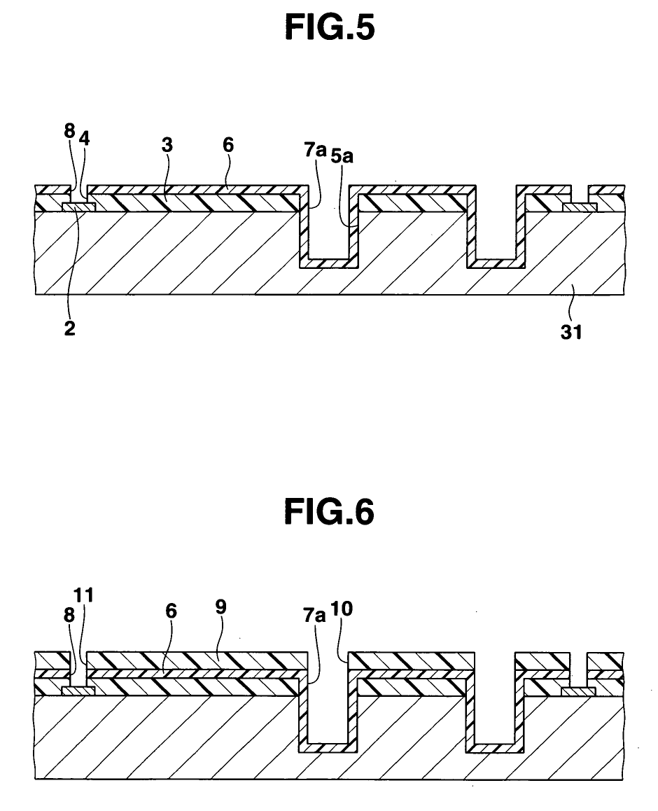

Next, as shown in FIG. 5, the second upper-layer insulating film 6 made from silicon nitride is formed over the surface of the silicon substrate 1 including the recessed portions 5a via the plasma CVD (chemical vapor deposition) method. As shown in FIG. 5, the second upper-layer insulating film 6 formed adjacent to the inner wall surfaces of the recessed portions 5a remains in the cylindrical state with the bottom that exists in the recessed portion 7a. Next, by applying the photo-lithographic method, an opening 8 is formed through the second upper-layer insulating film 6 at a portion corresponding to the opening 4 formed through the first upper-layer insulating film 3.

Next, as shown in FIG. 6, by applying the screen printing method or the spin-coating method, the third upper-layer insulating film 9 made from polyimide resin is formed over the surface of the second upper-layer insulating film 6. Next, by applying the photo-lithographic method, a couple of openings 10 and 11 are formed through the third upper-layer insulating film 9 at the portions corresponding to the recessed portion 7a and the opening 8 formed through the second upper-layer insulating film 6.

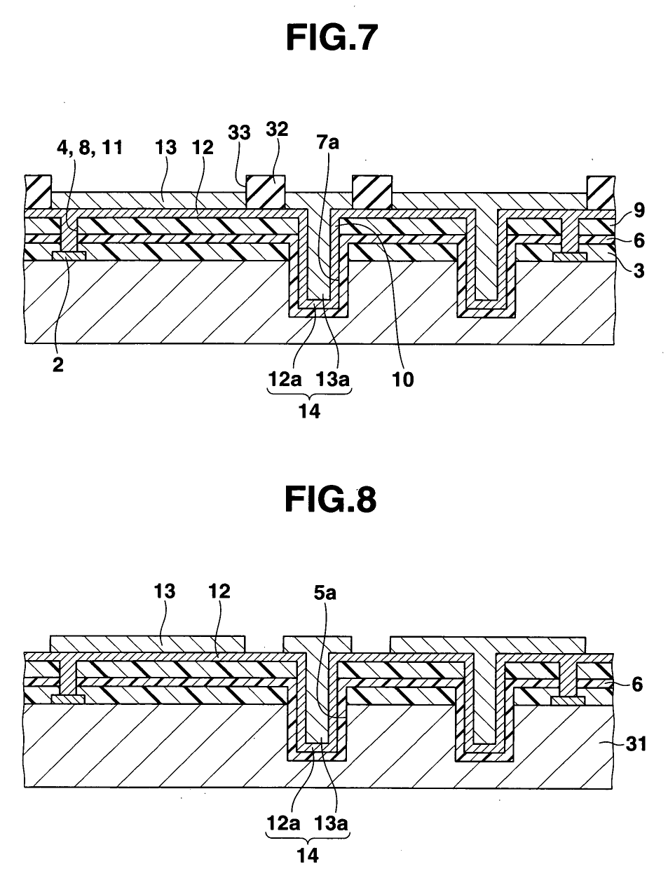

Next, as shown in FIG. 7, the ground metallic layer 12 is formed over the whole surface of the third upper-layer insulating film 9 including the upper surface of the connecting pads 2 exposed via the openings 4, 8, and 11 formed through the first, second, and the third upper-layer insulating films 3, 6, and 9. In this case, the ground metallic layer 12 may solely consist of a copper layer deposited via a non-electrolytic plating process or solely consist of a copper layer deposited via a sputtering process or the ground metallic layer 12 may also comprise a copper layer deposited on a thin film layer of titanium formed via a sputtering process by further applying a sputtering process thereto. The same applies to the case of a ground metallic layer 23 for the thin-film inductive element to be described later on.

Next, pattern of a plating resist film 32 is formed over the surface of the ground metallic layer 12. In this case, an opening 33 is formed through the plating resist film 32 at an area corresponding to the area for distributing the wirings 13. Next, by executing a copper electrolytic plating process via the ground metallic layer 12 as the plating current path, the wirings 13 is distributed over the surface of the ground metallic layer 12 in the opening 33 formed through the plating resist film 32. Referring to the condition shown in FIG. 7, the vertical conductor 14 is formed by means of the recessed portion 7a of the second upper-layer insulating film 6, the ground metallic layer 12a which is cylindrically formed at the bottom of the inner wall surface of the opening 10 formed through the third upper-layer insulating film 9, and the copper portion 13a formed inside the opening 10.

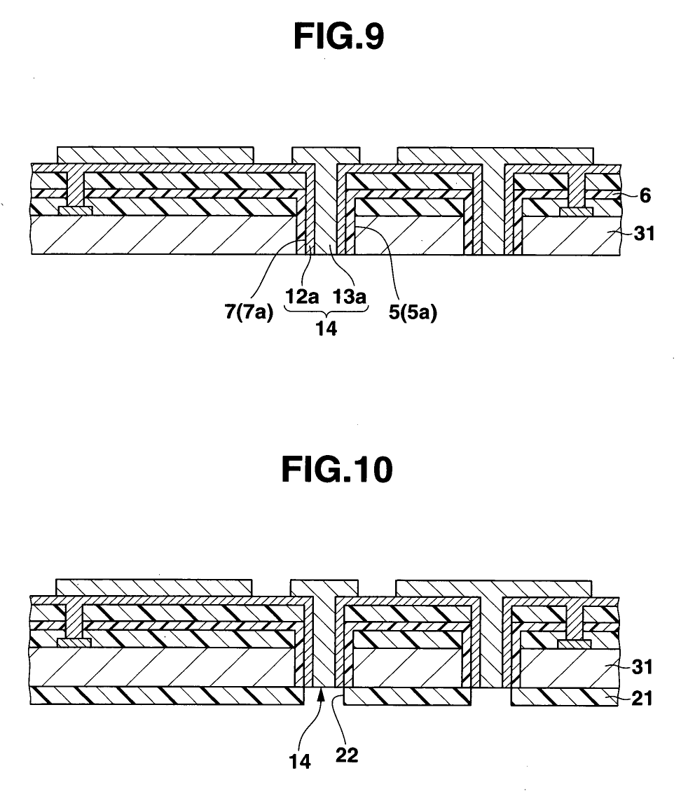

Next, when the plated resist film 32 is removed, the semiconductor wafer 31 appears as the one shown in FIG. 8. Next, a grinding process is executed against the second upper-layer insulating film 6 formed in the recessed portion 5a of the semiconductor wafer 31 and the bottom surface of the semiconductor wafer 31 including the ground metallic layer 12 until causing the bottom surface of the copper portion 13a to be at least exposed, the resultant semiconductor wafer 31 appears as shown in FIG. 9.

In the condition shown in FIG. 9, a through-hole 5 comprising the remainder of the recessed portion 5a is formed through the semiconductor wafer 31. Further, another through-hole 7 comprising the remainder of the recessed portion 7a is formed through the cylindrical second upper-layer insulating film 6 formed in the through-hole 5. The bottom surfaces of the cylindrical second upper-layer insulating film 6 formed in the through-hole 5 of the semiconductor wafer 31, the cylindrical ground metallic layer 12a, and the copper portion 13a are uniformly flush with the bottom surface of the semiconductor wafer 31. It is allowable to grind the bottom surfaces of the cylindrical ground metallic layer 12a and the copper portion 13a to some extent in conjunction with the semiconductor wafer 31.

Next, as shown in FIG. 10, by applying the screen printing method or the spin-coating method, a ground insulating film 21 made from polyimide resin is formed beneath the bottom of the semiconductor wafer 31. Next, by applying the photo-lithographic method, an opening 22 is formed through the ground insulating film 21 at a portion corresponding to the bottom surface of the vertical conductor 14.

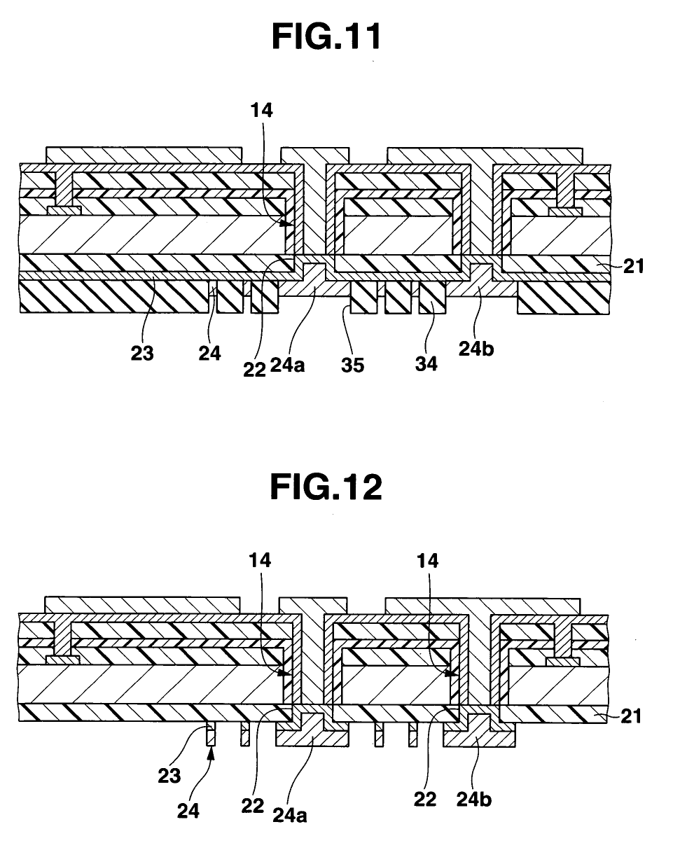

Next, as shown in FIG. 11, by applying the sputtering method, a ground metallic layer 23 for the thin-film inductive element is made from copper by covering the whole bottom surface of the ground insulating film 21 including the bottom surface of the vertical conductor exposed via the opening 22 formed through the ground insulating film 21. Next, pattern of the plating resist film 34 is formed beneath the ground metallic layer 23 for the thin-film inductive element. In this case, an opening 35 is formed through the plating resist film 34 at a portion corresponding to the area for the formation of the thin-film inductive element 24.

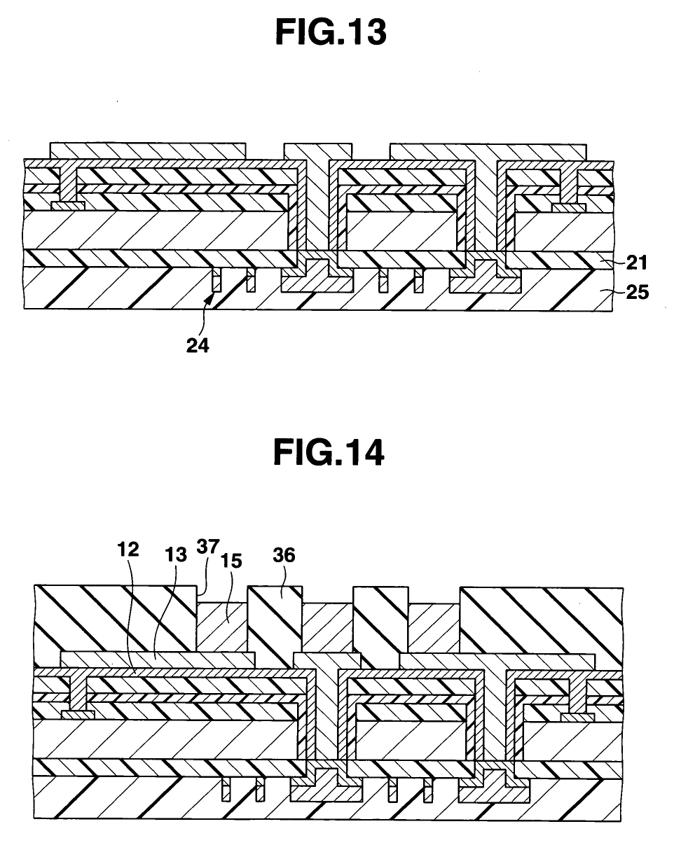

Next, by executing electrolytic plating of copper via the ground metallic layer 23 for the thin-film inductive element that functions as the plating current path, the thin-film inductive element 24 having the spirally configured plan-view shape is formed beneath the ground metallic layer 23 for the thin-film inductive element inside the opening 35 formed through the plating resist film 34. Next, the plating resist film 34 is stripped off, and then, by applying the thin-film inductive element 24 as mask, unwanted portion is removed from the ground metallic layer 23 for the thin-film inductive element via an etching process. In consequence, as shown in FIG. 12, the ground metallic layer 23 for the thin-film inductive element remains solely on the thin-film inductive element 24.

In the condition shown in FIG. 12, the inner and outer end portions of the thin-film inductive element 24 including the ground metallic layer 23 for the thin-film inductive element are respectively connected to the bottom surface of the vertical conductor 14 via the opening formed through the ground insulating film 21. Next, as shown in FIG. 13, by applying the screen printing method or the spin-coating method, a lower-layer over-coating film 25 comprising solder resist is formed beneath the ground insulating film 21 including the thin-film inductive element 24.

Next, as shown in FIG. 14, the plating resist film 36 is patterned on the surface of the ground metallic layer 12 including the wirings 13. In this case, an opening 37 is formed through the plating resist film 36 at a portion corresponding to the connecting pads of the wirings 13, in other words, at a portion corresponding to the area where the column-shaped electrodes 15 are to be formed. Next, by executing electrolytic plating of copper via the ground metallic layer 12 that functions as the plating current path, the column-shaped electrodes 15 are formed over the surface of the connecting pads of the wirings 13 inside the opening 37 formed through the plating resist film 36.

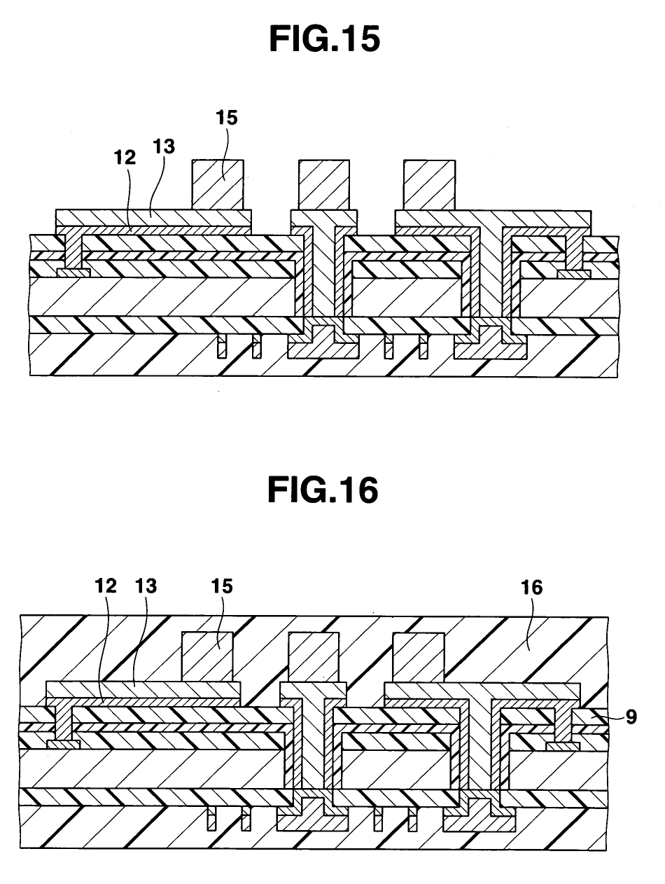

Next, the plating resist film 36 is removed, and then, unwanted portion of the ground metallic layer 12 is removed by an etching process using the wirings 13 that as a mask. Then, as shown in FIG. 15, the ground metallic layer 12 remains solely beneath the wirings 13. Next, as shown in FIG. 16, by applying the screen printing method or the spin-coating method, a sealing film 16 made of epoxy resin is formed over the surface of the third upper-layer insulating film 9 including the wirings 13 and the column-shaped electrodes 15 in order that the thickness of the sealing film 16 becomes thicker than the height of the column-shaped electrodes 15. Hence, in this condition, the upper surfaces of the column-shaped electrodes 15 are fully covered by the sealing film 16.

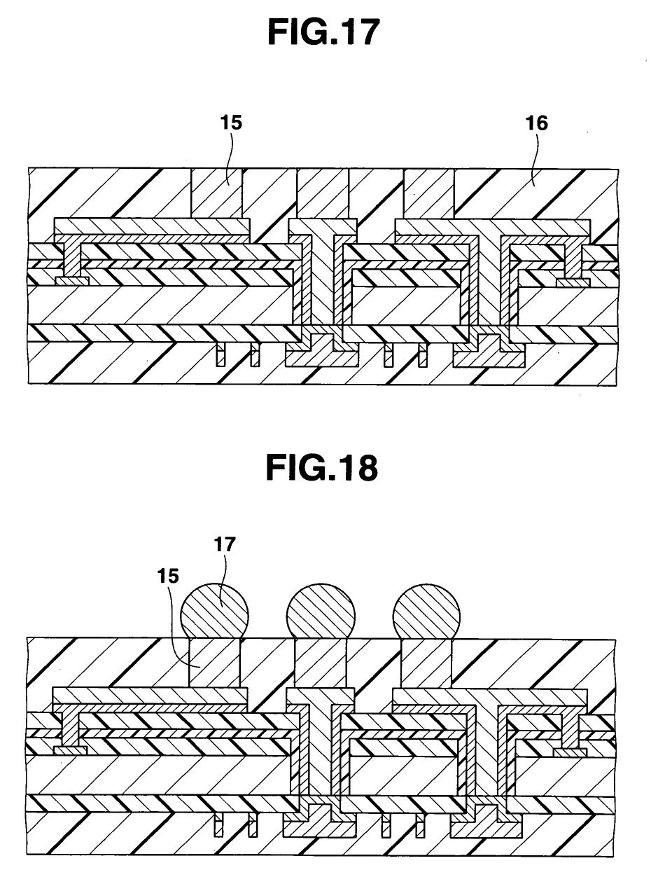

Next, the upper surface of the sealing film 16 is properly ground, and then, as shown in FIG. 17, the upper surfaces of the column-shaped electrodes 15 are exposed. Then, the upper surface of the sealing film 16 including the upper surfaces of the exposed column-shaped electrodes 15 is leveled off. Next, as shown in FIG. 18, a plurality of soldering balls 17 are formed on the upper surfaces of the column-shaped electrodes 15. Next, a dicing process is executed. In consequence, a plurality of semiconductor devices as shown in FIG. 1 can be completed.

### The Second Embodiment

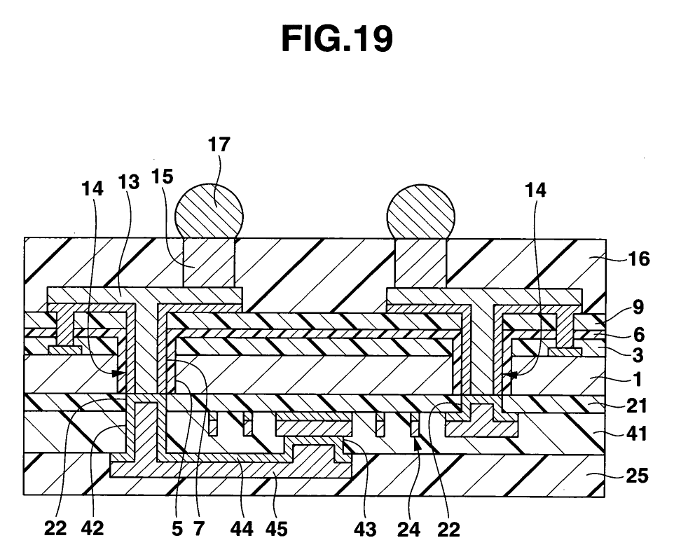

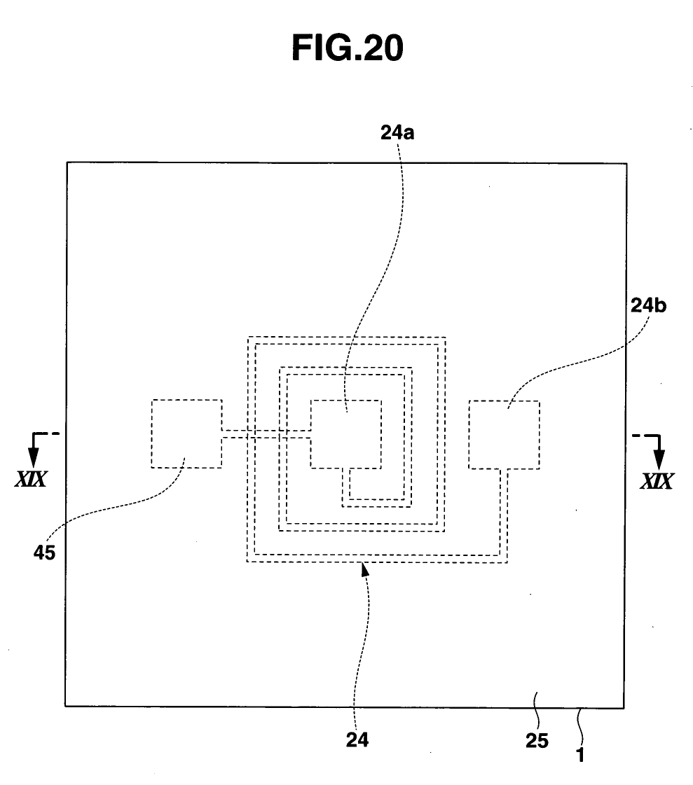

FIG. 19 designates a cross-sectional view of the essential components of the semiconductor device according to the second embodiment of the present invention. FIG. 20 designates a bottom surface plan view of the semiconductor device according to the second embodiment of the present invention. In this case, FIG. 19 designates a cross-sectional view along the line XIX-XIX shown in FIG. 20. The semiconductor device according to the second embodiment has a configuration that is distinctly different from that of the preceding semiconductor device shown in FIG. 1 and FIG. 2. Concretely, the present semiconductor device is fitted with a couple of vertical conductors 14 at a couple of predetermined portions in the periphery of a silicon substrate 1 instead of providing a vertical conductor 14 at the center of the silicon substrate 1. Further, the present semiconductor device is fitted with a wiring unit for a thin-film inductive element.

More particularly, a couple of through-holes 5 are formed at a couple of predetermined portions in the periphery of the silicon substrate 1. A couple of vertical conductors 14 are provided inside a couple of through-holes 7 adjoining the second upper-layer insulating film 6 formed in the through-holes 5. A lower-layer insulating film 41 made from polyimide resin is formed beneath the bottom surface of the ground insulating film 21 including the thin-film inductive element 24. An opening 42 is formed through the lower-layer insulating film 41 at a portion corresponding to one of the openings 22 on the part of the ground insulating film 21. Another opening 43 is formed through the lower-layer insulating film 41 at a portion that corresponds to the center of the inner end portion of the thin-film inductive element 24.

A wiring unit 45 for the thin-film inductive element including a ground metallic layer 44 is distributed beneath the surface of the lower-layer insulating film 41. An end of the wiring unit 45 for the thin-film inductive element including the ground metallic layer 44 is connected to the bottom surface of one of the vertical conductors 14 via the openings 22 and 42 formed through the ground insulating films 21 and 41. The other end of the wiring unit 45 for the thin-film inductive element including the ground metallic layer 44 is connected to an inner end portion 24a of the thin-film inductive element 24 via the opening 43 formed through the lower-layer insulating film 41. An outer end portion 24b of the thin-film inductive element 24 is connected to the bottom surface of the other vertical conductor 14 via the opening 21 formed through the ground insulating film 21. A bottom layer over-coating film 25 is formed beneath the bottom surface of the ground insulating film 41 including the wiring unit 45 for the thin-film inductive element 24.

In the present semiconductor device according to the second embodiment, a couple of vertical conductors 14 are formed at a couple of predetermined portions in the periphery of the silicon substrate 1, in other words, the vertical conductors 14 are not disposed at the center of the silicon substrate 1. This in turn makes it possible to effectively utilize the whole upper surface at the center of the silicon substrate 1. For example, it is possible to form integrated circuits throughout the whole upper surface at the center of the silicon substrate 1.

Since the method of manufacturing the present semiconductor device is easily comprehensible from the above-described manufacturing method, further description thereof is deleted.

### The Third Embodiment

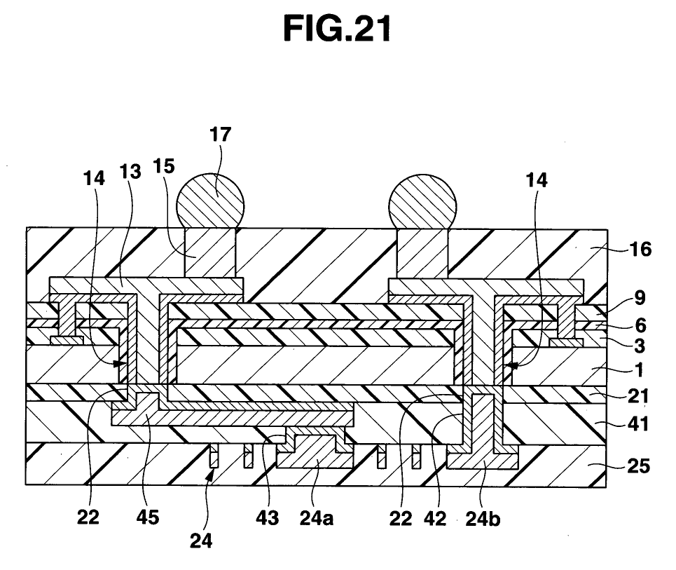

FIG. 21 shows a cross-sectional view of the essential components of the semiconductor device according to the third embodiment of the present invention. The present semiconductor device has a configuration that is distinctly different from that of the preceding semiconductor device shown in FIG. 19 in the following points: Specifically, the third embodiment provides a wiring unit 45 for the thin-film inductive element 24 beneath the bottom surface and also provides the thin-film inductive element 24 beneath the bottom surface of the lower-layer insulating film 41.

In this case, an end portion of the wiring unit 45 for the thin-film inductive element is connected to the bottom surface of one of the vertical conductors 14 via an opening 22 formed through the ground insulating film 21. An inner end portion 24a of the thin-film inductive element 24 is connected to the other end portion of the wiring unit 45 for the thin-film inductive element 24 via an opening 43 formed through the lower-layer insulating film 41. An outer end portion 24b of the thin-film inductive element 24 is connected to the bottom surface of the other vertical conductor 14 via openings 22 and 42 respectively formed through the lower-layer insulating films 21 and 41. Further, a lower-layer over-coating film 25 is formed beneath the bottom surface of the lower-layer insulating film 41 by way of fully concealing the thin-film inductive element 24.

Since the method of manufacturing the present semiconductor device is easily comprehensible from the above-described manufacturing method, further description thereof is deleted.

### The Fourth Embodiment

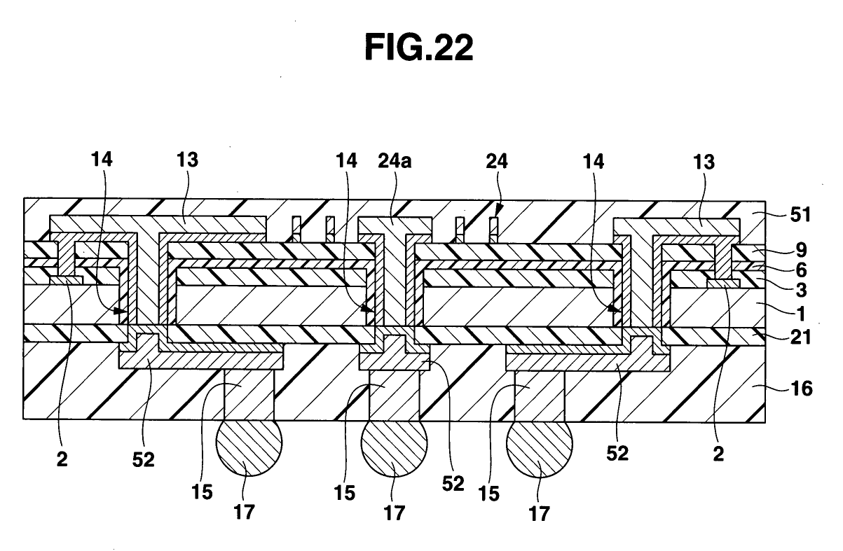

FIG. 22 shows a cross-sectional view of the essential components of the semiconductor device according to the fourth embodiment of the present invention. The present semiconductor device has a configuration that is distinctly different from that of the preceding semiconductor device shown in FIG. 1 in the following points. Specifically, the wirings 13, the thin-film inductive element 24, and the upper-layer over-coating film 51, are respectively disposed over the surface of the third upper-layer insulating film 9, and further, the lower-layer wiring units 52, the column-shaped electrodes 15, a sealing film 16, and soldering balls 17, are respectively disposed beneath the bottom surface of the ground insulating film 21.

In this case, an outer end portion of the thin-film inductive element 24 is connected to a predetermined single wirings 13. An inner end portion 24b of the thin-film inductive element 24 is connected to a predetermined lower-layer wiring unit 52 via the vertical conductor 14 provided at the center portion of the silicon substrate 1. The wirings 13 are connected to the lower-layer wiring unit 52 via the other vertical conductor 14 disposed at the other predetermined portion of the silicon substrate 1.

The fourth embodiment of the semiconductor device provides the thin-film inductive element 24 on the upper surface of the silicon substrate 1 and further provides a plurality of lower-layer wiring units 52 beneath the bottom surface of the silicon substrate 1 such that the lower-layer wiring units 52 can respectively be connected to the column-shaped electrodes 15. Hence, it is not necessary to secure a certain area otherwise needed for the formation of the thin-film inductive element 24 beneath the bottom surface of the silicon substrate 1, i.e. beneath the bottom surface of the ground insulating film 21 that accommodates formation of the lower-layer wiring unit 52. This in turn makes it possible to evade restraint that affects distribution of the lower-layer wiring unit 52 formed beneath the bottom surface of the ground insulating film 21 even when the thin-film inductive element 24 is built therein. Since the method of manufacturing the present semiconductor device may easily be comprehended from the above-described manufacturing method, further description thereof is deleted.

### The Fifth Embodiment

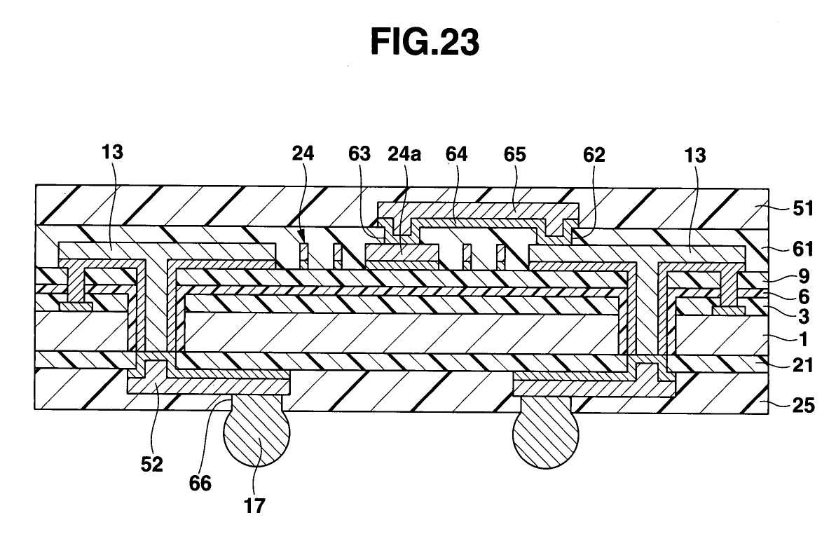

FIG. 23 designates a cross-sectional view of the essential components of the semiconductor device according to the fifth embodiment of the present invention. The present semiconductor device has a configuration that is distinctly different from that of the preceding semiconductor device shown in FIG. 22 in the following points. Specifically, instead of providing the vertical conductor 14 at the center portion of the silicon substrate 1, a wiring unit 65 for the thin-film inductive element 24 is provided. The fifth embodiment has deleted provision of the column-shaped electrodes 15 and the sealing film 16, but instead, soldering balls 17 have been formed directly beneath the bottom surface of the connecting pad of the lower-layer wiring assembly 51.

Concretely, the fourth upper-layer insulating film 61 made from polyimide resin is formed over the surface of the third upper-layer insulating film 9 including the wirings 13 and the thin-film inductive element 24. Openings 62 and 63 are formed through the fourth upper-layer insulating film 61 at the portions corresponding to the other end of the wirings 13 and the inner end of the thin-film inductive element 24.

An end of the wiring unit 65 for the thin-film inductive element 24 including the ground metallic layer 64 formed over the surface of the fourth upper-layer insulating film 61 is connected to the wirings 13 via the opening 62 formed through the fourth upper-layer insulating film 61.

The other end of the wiring unit 65 for the thin-film inductive element 24 including the ground metallic layer 64 is connected to the inner end 24a of the thin-film inductive element 24 via the opening 63 formed through the fourth upper-layer insulating film 61. The outer end of the thin-film inductive element 24 is connected to the wirings 13. An upper-layer over-coating film 51 is formed over the surface of the fourth upper-layer insulating film 61 including the wiring unit 65 for the thin-film inductive element 24.

A lower-layer over-coating film 25 is formed beneath the bottom surface of the ground insulating film 21 including the ground wiring unit 52. Another opening 66 is formed through the lower-layer over-coating film 25 at a portion corresponding to the connecting pad of the lower-layer wiring unit 52. Soldering balls 17 are formed in the opening 66 and beneath the opening 66 formed through the lower-layer over-coating film 25 in the state being linked with the connecting pad of the lower-layer wiring unit 52. Note that, since the method of manufacturing the present semiconductor device can easily be comprehended from the above-described manufacturing method, further description thereof is deleted.

### Other Embodiments

According to the inventive semiconductor device shown in FIGS. 1 and 2 for example, a through hole 5 is formed through the center of the silicon substrate 1. The inner end of the thin-film inductive element 24 disposed beneath the bottom surface of the silicon substrate 1 is connected to the bottom surface of the vertical conductor 14 disposed inside the through-hole 5. It should be understood however that the practical scope of the present invention is not solely limited to this configuration. For example, in the case in which a number of integrated circuits have been formed throughout the whole upper surface at the center of the silicon substrate 1, it is also allowable to implement such an arrangement as cited below. Concretely, a through-hole 5 may be formed through the silicon substrate 1 in the periphery of the integrated circuits, where it is allowable to connect the inner end of the thin-film inductive element 24 disposed beneath the bottom surface of the silicon substrate 1 to the bottom surface of the vertical conductor 14 disposed inside the through-hole 5. In this case, it is also allowable to provide a plurality of thin-film inductive elements 24 beneath the bottom surface of the silicon substrate 1.

According to the present invention, a plurality of wiring units are disposed on the one-surface of a semiconductor substrate, whereas a thin-film circuit element is disposed on the other surface thereof. As an alternative arrangement, a thin-film circuit element is disposed on the one-surface of the semiconductor substrate, whereas a plurality of wiring units other than that of the above case are disposed on the other surface side thereof. Hence, it is not necessary to secure a certain area on the one-surface side or on the other surface side of the semiconductor substrate otherwise needed for the formation of the thin-film circuit element. Hence, even when the thin-film circuit element has been provided, it is possible to evade restraint that affects the distribution of the wiring units disposed on the one-surface side (or on the other surface side) of the semiconductor substrate (or distribution of other wiring units), thereby making it possible to provide a useful semiconductor device that is appropriately provided with satisfactory wiring distribution.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2007-045167 filed on Feb. 26, 2007 and including specification, claims, drawings and summary. The disclosure of the above Japanese Patent Application is incorporated herein by reference in its entirety.

What is claimed is:

1. A semiconductor device comprising:
a semiconductor substrate having a plurality of connecting pads formed on a one-surface thereof;
a plurality of the first wirings disposed on the one-surface thereof in such a way as to be connected to the connecting pads;
a thin-film circuit element formed on the other surface of the semiconductor substrate; and
vertical conductors formed in the semiconductor substrate so as to connect the thin-film circuit element with the wirings.

2. The semiconductor device according to claim 1, wherein the thin film circuit element comprises a thin-film inductive element which is spirally configured.

3. The semiconductor device according to claim 2, wherein the inner and outer end portions of the thin-film circuit element are respectively connected to the vertical conductors formed at two locations in the semiconductor substrate.

4. The semiconductor device according to claim 2, further comprising: a second wiring and a third wiring for the thin-film inductive element, the second wiring and the third wiring being disposed on another layer which is a different layer from a layer of the thin-film inductive element formed on the other surface of the semiconductor substrate, wherein the second wiring is connected to one of the vertical conductors and the third wiring is connected to another one of the vertical conductors.

5. The semiconductor device according to claim 1, wherein a plurality of column-shaped electrodes are formed on the connecting pads provided for the first wirings.

6. The semiconductor device according to claim 5, wherein a sealing film is formed in the periphery of the column-shaped electrodes.

7. The semiconductor device according to claim 6, wherein soldering balls are disposed on the column-shaped electrodes.

8. The semiconductor device according to claim 1, wherein an over-coating film is provided for covering component elements other than the connecting pads provided for the first wirings.

9. The semiconductor device according to claim 8, wherein the soldering balls are formed on the connecting pads provided for the first wirings.

10. A semiconductor device comprising:
a semiconductor substrate having a plurality of connecting pads formed on one-surface thereof;
a plurality of the first wirings disposed on the one-side surface of the semiconductor substrate in such a way as to be connected to the connecting pads;
a thin-film circuit element that is essentially a spirally configured thin-film inductive element disposed on the other side surface of the semiconductor substrate; and
a vertical conductor formed in the semiconductor substrate so as to enable the thin-film circuit element to be connected to the first wirings.

11. A semiconductor device comprising:
a semiconductor substrate having a plurality of connecting pads formed on the one-surface thereof;
a plurality of first wirings disposed on the one-surface of the semiconductor substrate in such a way as to be individually connected to the connecting pads;
a thin-film circuit element formed on the one-surface of the semiconductor substrate in such a way as to be connected to the first wirings;
a plurality of second wirings formed on the other surface of the semiconductor substrate; and
vertical conductors formed in the semiconductor substrate so as to connect the first wirings to be connected to the second wirings.

12. The semiconductor device according to claim 11, wherein the thin-film circuit element is a spirally configured thin-film inductive element.

13. The semiconductor device according to claim 12, wherein the outer end of the thin-film inductive element is connected to the first wirings, whereas the inner end of the same thin-film inductive element is connected to the second wirings via the second vertical conductor disposed in the semiconductor substrate.

14. The semiconductor device according to claim 12, wherein the second wirings for the thin-film inductive element are disposed on another layer which is a different layer from a layer of the thin-film inductive element, one of the second wirings being connected to one of the vertical conductors and another one of the wirings being connected to another one of the vertical conductors.

15. The semiconductor device according to claim 1, wherein a plurality of column-shaped electrodes are disposed on the connecting pads of the second wirings.

16. The semiconductor device according to claim 15, wherein a sealing film is provided in the periphery of the column-shaped electrodes.

17. The semiconductor device according to claim 16, wherein a plurality of soldering balls are provided on the column-shaped electrodes.

18. The semiconductor device according to claim 11, wherein an over-coating film is provided for covering component elements other than the connecting pads of the second wirings.

19. The semiconductor device according to claim 18, wherein a plurality of soldering balls are provided on the connecting pads of the second wirings.

20. A semiconductor device comprising:
a semiconductor substrate having a plurality of connecting pads formed on a one-surface thereof;
a plurality of first wirings disposed on the one-surface of the semiconductor substrate in such a way as to be connected to the connecting pads;
a thin-film circuit element, which is essentially a spirally configured thin-film inductive element provided on the one-surface of the semiconductor substrate in such a way as to be connected to the first wirings;
a plurality of second wirings disposed on the other surface of the semiconductor substrate; and
vertical conductors formed in the semiconductor substrate so as to connect the first wirings to be connected to the second wirings.
